(19) United States
(12) Patent Application Publication
(10) Pub. No.: US 2026/0164582 A1
(43) Pub. Date: Jun. 11, 2026

(54) DISPLAY APPARATUS

(71) Applicant: KORTEK CORPORATION, Incheon (KR)

(72) Inventors: Kyung In SEO, Incheon (KR); Hyuk Sung KWON, Incheon (KR)

(21) Appl. No.: 19/409,886

(22) Filed: Dec. 5, 2025

(30) Foreign Application Priority Data
Dec. 11, 2024 (KR) 10-2024-0183354

(51) Int. Cl. H05K 5/03

(52) U.S. Cl. CPC H05K 5/03

(57) ABSTRACT

A display apparatus is provided including a display module having a display panel, a protective panel attached to a front surface of the display module via a double-sided adhesive tape, a frame supporting the display module, a cover covering a rear surface of the frame and in contact with the protective panel, a fastening bolt configured to press the cover toward the frame so that the cover is fixed to the frame, and an elastic member configured to elastically press the fastening bolt in a direction opposite to a direction in which the fastening bolt presses the cover.

### CROSS REFERENCE TO RELATED APPLICATION

This application claims priority to and the benefit of Korean Patent Application No. 10-2024-0183354, filed on December 11, 2024, the disclosure of which is incorporated herein by reference in its entirety.

### FIELD OF TECHNOLOGY

The following relates to a display apparatus, and more particularly, to a display apparatus including a cover and a protective panel.

### BACKGROUND

A display apparatus is a device that receives a video signal and displays an image such as a still image or moving image on a front surface thereof, for example, a monitor. A display apparatus includes a display panel on which a video is displayed, a protective panel that protects a front surface of the display panel on which the video is displayed, and a cover that covers a rear surface of the display panel.

A display apparatus may include a bezel on which a video is not displayed on the front surface thereof. The bezel is formed on an outer corner of the front surface of the display apparatus. In order to minimize the bezel, reduce a manufacturing cost, and improve the aesthetics of the display apparatus, the display apparatus may have a structure in which a front end of the cover is in contact with a rear surface of the protective panel.

However, in a display apparatus with this structure, a phenomenon in which the protective panel is pressed by the cover and separated from the display panel may occur.

The conventional art of embodiments of the present invention is disclosed in Korean Laid-Open Patent Application No. 10-2023-0163618 (published on December 1, 2023, entitled “Back cover assembly for display device”).

### SUMMARY

An aspect relates to a display apparatus in which a protective panel is not separated from a display panel.

According to an aspect of embodiments of the present invention, there is provided a display apparatus including a display module having a display panel, a protective panel attached to a front surface of the display module via a double-sided adhesive tape, a frame supporting the display module, a cover covering a rear surface of the frame and in contact with the protective panel, a fastening bolt configured to press the cover toward the frame so that the cover is fixed to the frame, and an elastic member configured to elastically press the fastening bolt in a direction opposite to a direction in which the fastening bolt presses the cover.

The fastening bolt may include a body portion configured to pass through the frame and provided with a male screw pattern on an outer surface thereof, a head portion having a diameter that is greater than a diameter of the body portion, and an intermediate portion located between the body portion and the head portion and having a diameter that is greater than the diameter of the body portion and is smaller than the diameter of the head portion.

The cover may include a panel overlapping the frame in a front-rear direction of the display apparatus, and a cover through-hole provided with a groove concavely formed in a rear surface of the panel and an intermediate portion through-hole formed to pass through a bottom surface of the groove and having an inner diameter that is greater than the diameter of the intermediate portion and is smaller than the diameter of the head portion.

The elastic member may be interposed between the bottom surface and the head portion and inserted into the groove.

The elastic member may be formed of a rubber material and provided with a hollow through which the intermediate portion passes, and the head portion does not pass.

The cover may further include a protective panel contact portion in contact with an outer periphery of a rear surface of the protective panel.

The display apparatus may further include a nut that includes a female screw pattern engaged with the male screw pattern of the body portion and is in contact with a front surface of the frame.

The frame may be provided with a body portion through-hole having an inner diameter that is greater than the diameter of the body portion so that the body portion may pass through the body portion through-hole, the nut is provided with a nut body having a hollow in which the female screw pattern is formed on an inner surface of the nut body, and the display apparatus may further include a ring-shaped guide protruding rearward from a rear surface of the nut body to surround the body portion and to be inserted into the body portion through-hole.

The nut may further include a friction protrusion that protrudes rearward from the rear surface of the nut body and prevent the nut from rotating relative to the frame while in close contact with the front surface of the frame.

The display apparatus may further include a washer provided with a washer hollow through which the body portion passes, and which is interposed between a rear surface of the frame and the intermediate portion.

### BRIEF DESCRIPTION

Some of the embodiments will be described in detail, with reference to the following figures, wherein like designations denote like members, wherein:

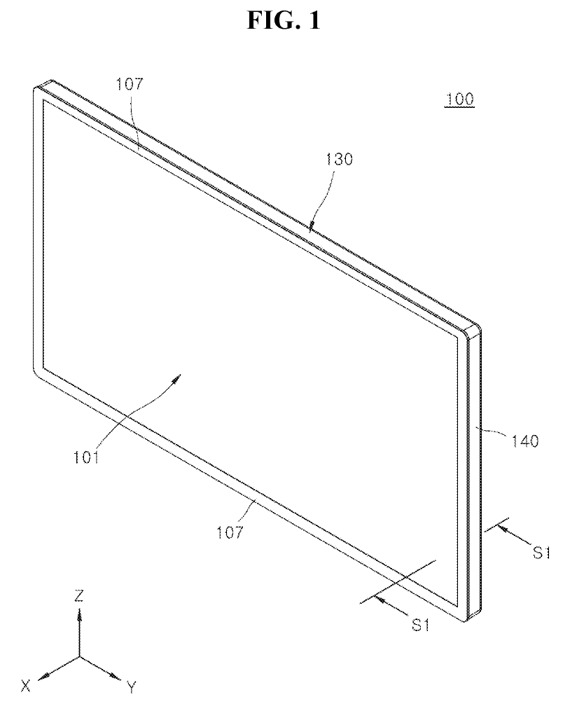

FIG. 1 shows a perspective view illustrating a display apparatus according to an embodiment of the present invention from the front;

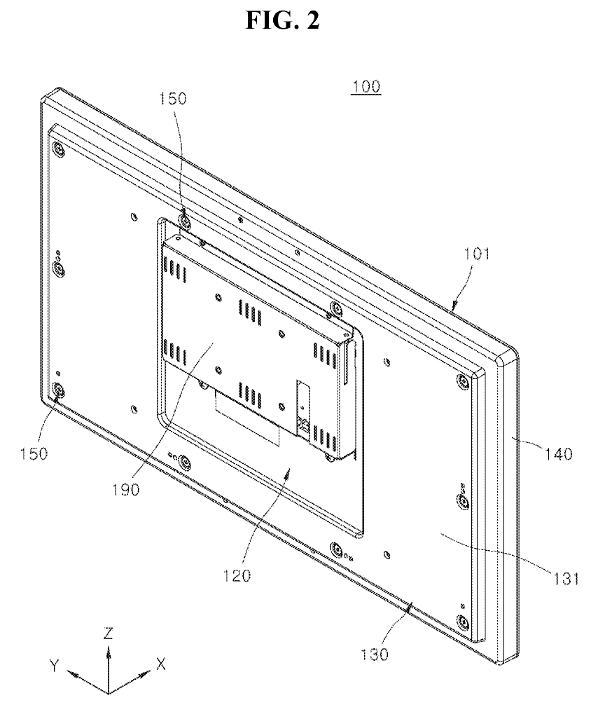

FIG. 2 shows a perspective view illustrating the display apparatus of FIG. 1 from the rear;

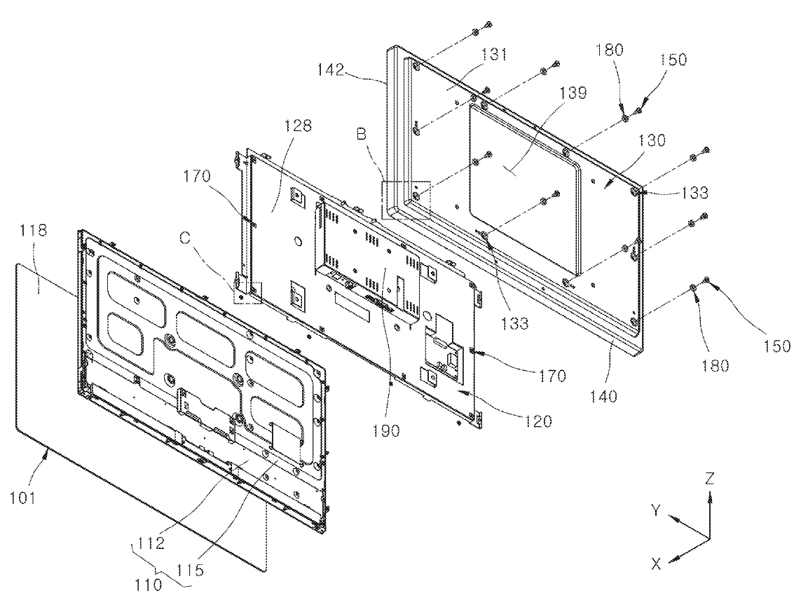

FIG. 3 shows an exploded perspective view illustrating the display apparatus of FIG. 2 from the rear;

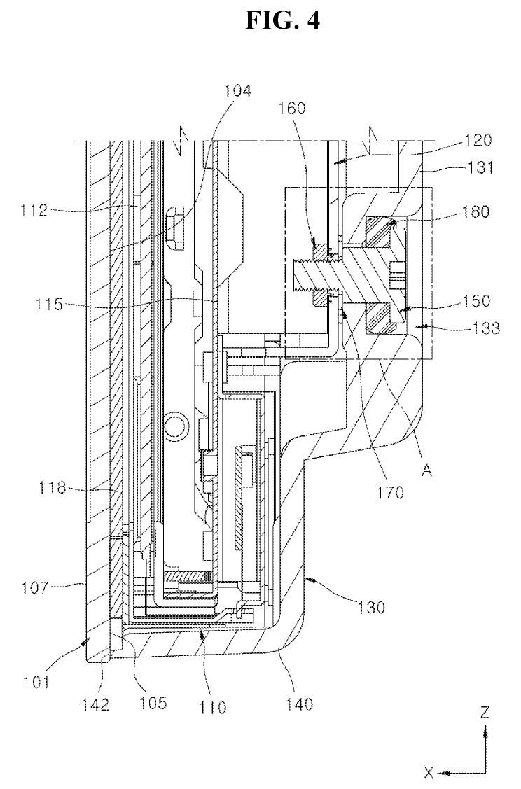

FIG. 4 shows a cross-sectional view along line S1-S1 of FIG. 1;

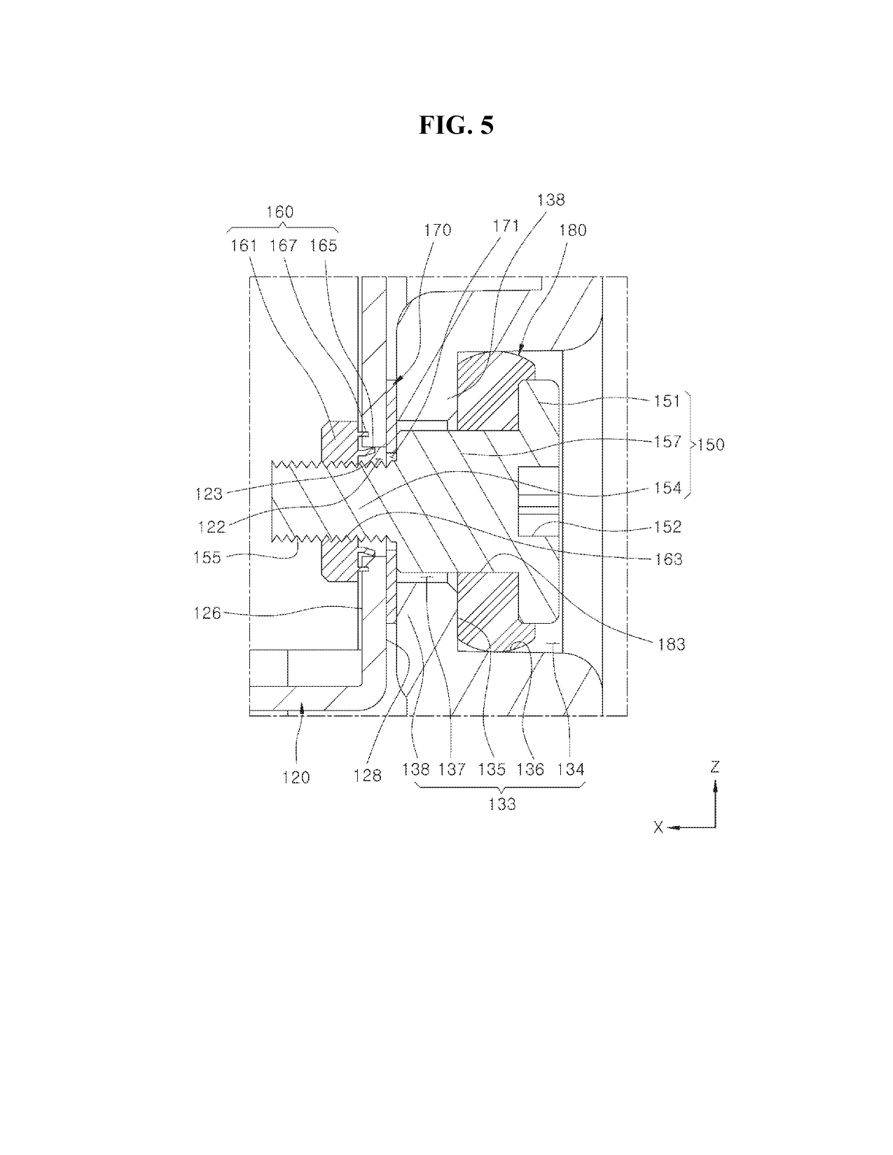

FIG. 5 shows an enlarged cross-sectional view illustrating portion A of FIG. 4;

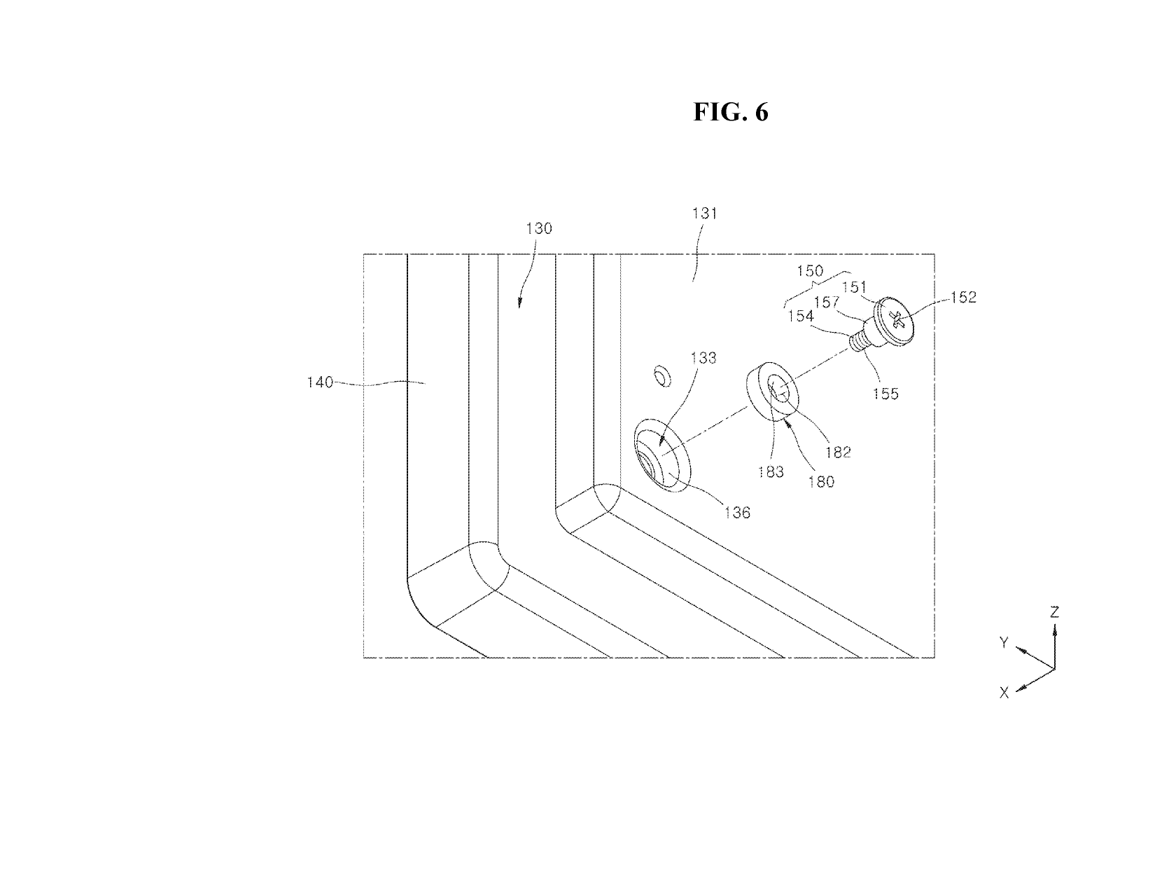

FIG. 6 shows an enlarged exploded perspective view illustrating portion B of FIG. 3, a fastening bolt, and an elastic body; and

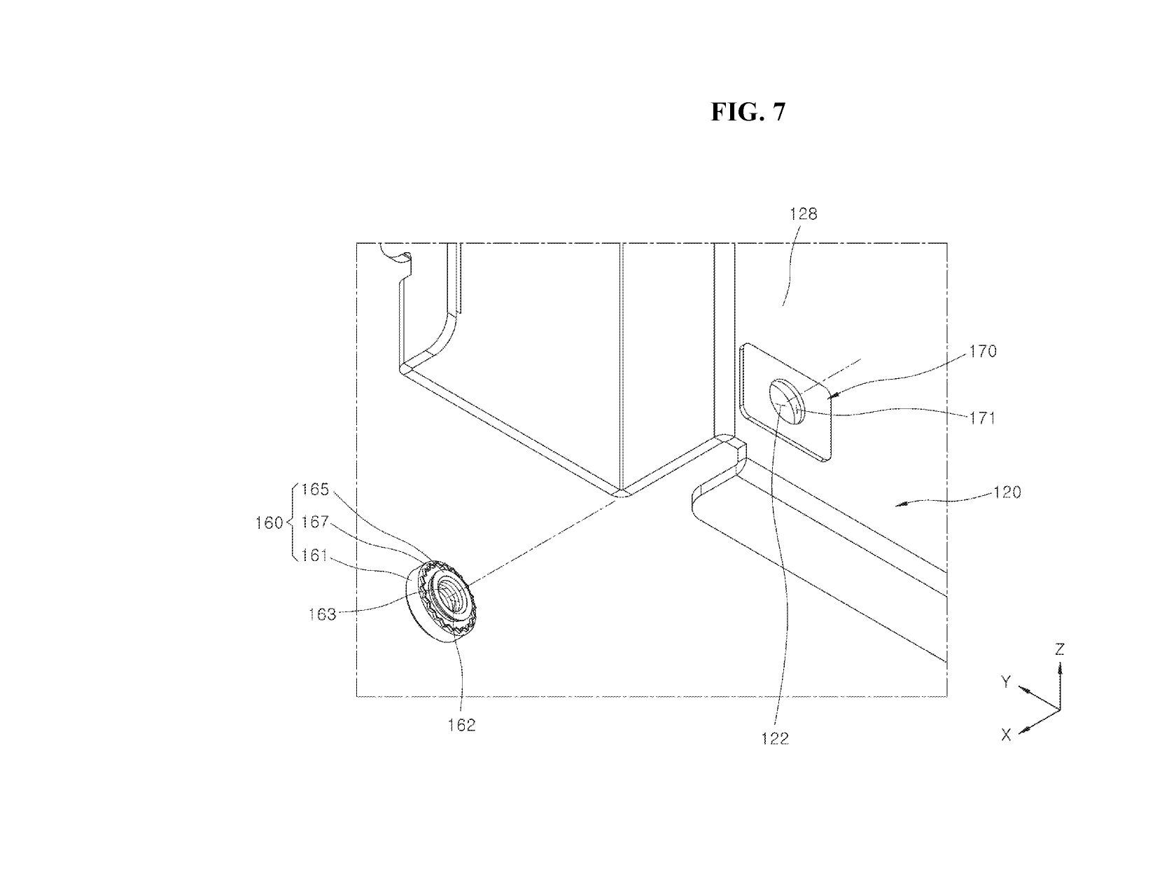

FIG. 7 shows an enlarged exploded perspective view illustrating portion C of FIG. 3.

### DETAILED DESCRIPTION

Hereinafter, a display apparatus according to embodiments of the present invention will be described with reference to the accompanying drawings. The terminology used in this specification is used to appropriately express exemplary embodiments of the present invention and may vary depending on the intent of the user or operator or the customs of the field to which embodiments of the present invention pertain. Therefore, these terms should be defined on the basis of the content throughout the present specification.

FIG. 1 is a perspective view illustrating a display apparatus according to an embodiment of the present invention from the front, FIG. 2 is a perspective view illustrating the display apparatus of FIG. 1 from the rear, FIG. 3 is an exploded perspective view illustrating the display apparatus of FIG. 2 from the rear, FIG. 4 is a cross-sectional view along line S1-S1 of FIG. 1, FIG. 5 is an enlarged cross-sectional view illustrating portion A of FIG. 4, FIG. 6 is an enlarged exploded perspective view illustrating portion B of FIG. 3, a fastening bolt, and an elastic body, and FIG. 7 is an enlarged exploded perspective view illustrating portion C of FIG. 3.

Referring to FIGS. 1 to 7, a display apparatus 100 according to an embodiment of the present invention includes a display module 110, a protective panel 101, a frame 120, a cover 130, a fastening bolt 150, and an elastic member 180. The display apparatus 100 may be installed, for example, inside a case of an arcade game machine, a case of a slot machine, or a case of a monitor.

The display module 110 may include a display panel 112 on which a video is displayed on a front surface, and a panel bracket 115 that supports the display panel 112 without obscuring the front surface of the display panel 112.

The display panel 112 may further include a liquid crystal panel and a backlight unit (BLU) disposed to overlap the liquid crystal panel at a rear side of the liquid crystal panel. The backlight unit may emit light forward toward the liquid crystal panel.

Meanwhile, a display apparatus according to an embodiment of the present invention may include a different type of display panel instead of the display panel including the liquid crystal panel and the backlight unit.

The protective panel 101 is attached to the front surface of the display module 110 via a double-sided adhesive tape 118. The protective panel 101 may prevent the display panel 112 from being damaged. The protective panel 101 may be, for example, a transparent glass plate. An outer periphery of the protective panel 101 may be provided with a bezel 107 coated with an opaque ink.

The frame 120 supports the display module 110. The frame 120 may be disposed at a rear side of the display module 110 to overlap the display module 110. The frame 120 may be formed of a metal material such as, for example, stainless steel.

Based on FIGS. 1 to 7, an X-axis direction may be a front-rear direction, a Y-axis direction may be a left-right direction, and a Z-axis direction may be a vertical direction. A positive (+) direction of the X-axis may be a direction from a rear side to a front side of the display panel 112, a positive (+) direction of the Y-axis may be a direction from a right side to a left side of the display panel 112, and a positive (+) direction of the Z-axis may be a direction from a bottom to a top of the display panel 112.

The X-axis direction may be a thickness direction of the display panel 112, the Y-axis direction may be a width direction of the display panel 112, and the Z-axis direction may be a height direction of the display panel 112.

The cover 130 covers a rear surface 128 of the frame 120 and is in contact with the protective panel 101. The cover 130 may include a panel 131, a skirt 140, and a protective panel contact portion 142. For example, the cover 130 may be formed of a synthetic resin material.

The panel 131 may overlap the frame 120 in the front-back direction of the display apparatus 100. For example, the panel 131 may be positioned at a rear side of the frame 120 to overlap the rear surface 128 of the frame 120. The panel 131 may have a plate shape parallel to a Y-Z plane. A heat dissipation through-hole 139 that is open may be formed in a central portion of the panel 131.

The display apparatus 100 may further include a controller 190 for controlling a video displayed through the display panel 112. The controller 190 may be coupled to the rear surface 128 of frame 120 and pass through the heat dissipation through-hole 139 to protrude to a rear side of the panel 131. Accordingly, overheating of the controller 190 may be suppressed during an operation of the display apparatus 100.

The skirt 140 may be bent from an outer periphery of the panel 131 and protrude forward. The protective panel contact portion 142 may be in contact with the outer periphery of the protective panel 101, i.e., the bezel 107. The protective panel contact portion 142 may be a front-end portion of the skirt 140. The protective panel contact portion 142 may be in contact with a rear surface 105 of the protective panel 101. In an embodiment of the present invention, the protective panel contact portion 142 may be in contact with the rear surface 105 of the protective panel 101 that overlaps the bezel 107 in the front-rear direction of the display apparatus 100.

The fastening bolt 150 presses the cover 130 toward the frame 120 so that the cover 130 is fixed to the frame 120. The fastening bolt 150 may be provided as a plurality of fastening bolts 150. The plurality of fastening bolts 150 may be disposed to be spaced apart from each other along the outer periphery of the panel 131. Each fastening bolt 150 may pass through the cover 130 and the frame 120.

The elastic member 180 elastically presses the fastening bolt 150 in a direction opposite a direction in which the fastening bolt 150 presses the cover 130. The elastic member 180 may be provided as a plurality of elastic members 180 to correspond to the plurality of fastening bolts 150 in a one-to-one manner.

For example, the direction in which the fastening bolt 150 presses the cover 130 may be the positive (+) direction of the X-axis, that is, a direction from the rear side of the display apparatus 100 toward the front side, and a direction in which the elastic member 180 presses the fastening bolt 150 may be a negative (−) direction of the X-axis, that is, a direction from the front side of the display apparatus 100 toward the rear side.

Each fastening bolt 150 may include a body portion 154, a head portion 151, and an intermediate portion 157. The body portion 154 may pass through the frame 120. A male screw pattern 155 may be provided on an outer surface of the body portion 154.

The frame 120 may be provided with a body portion through-hole 122 having an inner diameter that is greater than a diameter of the body portion 154 so that the body portion 154 passes through the body portion through-hole 122. The body portion through-hole 122 may be provided as a plurality of body portion through-holes 122 to correspond to the plurality of fastening bolts 150 in a one-to-one manner.

The head portion 151 may have a diameter that is greater than the diameter of the body portion 154. The head portion 151 may be positioned further rearward than the body portion 154. A tool fitting hole 152 into which a tool (not shown) for rotating the fastening bolt 150 relative to the frame 120 and the cover 130 is fitted may be formed in the head portion 151.

The intermediate portion 157 may be located between the body portion 154 and the head portion 151. The intermediate portion 157 may have a diameter that is greater than the diameter of the body portion 154 and is smaller than the diameter of the head portion 151.

The intermediate portion 157 may extend radially from a rear end of the body portion 154 in a stepwise manner, and the head portion 151 may extend radially from a rear end of the intermediate portion 157 in a stepwise manner. The body portion 154, the intermediate portion 157, and the head portion 151 may be formed integrally. The fastening bolt 150 may be formed of, for example, a carbon steel material having excellent rigidity.

The cover 130 may further include a cover through-hole 133. The cover through-hole 133 may be provided with a groove 134 concavely formed in the rear surface of the panel 131, and an intermediate portion through-hole 137 formed to pass through a bottom surface 135 of the groove 134.

The groove 134 may include the bottom surface 135 that is stepped from the panel 131 and is parallel thereto, and an inner surface 136 bent to extend from an outer corner of the bottom surface 135 and connected to the panel 131.

The intermediate portion through-hole 137 may have an inner diameter that is greater than a diameter of the intermediate portion 157 and is smaller than the diameter of the head portion 151. The cover through-hole 133 may be provided as a plurality of cover through-holes 133 to correspond to the plurality of fastening bolts 150 in a one-to-one manner.

The display apparatus 100 may further include a nut 160. The nut 160 may include a female screw pattern 163 engaged with the male screw pattern 155 of the body portion 154. The nut 160 may be in contact with a surface of the frame 120 facing the front side, that is, the front surface 126.

In an embodiment of the present invention, the nut 160 may include a nut body 161, a ring-shaped guide 165, and a friction protrusion 167. A hollow 162 through which the body portion 154 of the fastening bolt 150 passes may be formed in the nut body 161. The female screw pattern 163 engaged with the male screw pattern 155 of the body portion 154 may be formed on an inner surface of the hollow 162.

The ring-shaped guide 165 may protrude rearward from a rear surface of the nut body 161 to surround the body portion 154 and to be inserted into the body portion through-hole 122 of the frame 120. A rear end of the ring-shaped guide 165 may be in contact with an inner surface of the body portion through-hole 122. Accordingly, the fastening bolt 150 and the nut 160 may not shake radially with respect to the center of the body portion through-hole 122.

The friction protrusion 167 may protrude rearward from the rear surface of the nut body 161. While in contact with the front surface 126 of the frame 120 around the body portion through-hole 122, the friction protrusion 167 prevents the nut 160 from rotating relative to the frame 120.

The friction protrusion 167 may be positioned further away from the center of the hollow 162 than the ring-shaped guide 165. For example, the friction protrusion 167 may extend along a star-shaped pattern based on the hollow 162.

When the friction protrusion 167 is in close contact with or stuck to the front surface 126 of the frame 120, it is difficult for the nut 160 to rotate relative to the frame 120. Therefore, since the engagement of the fastening bolt 150 and the nut 160 are not easily loosened or tightened, the cover 130 may be firmly and stably fixed to the frame 120.

The nut 160 may be formed of, for example, a carbon steel material having excellent rigidity. The nut 160 may be provided as a plurality of nuts 160 to correspond to the plurality of fastening bolts 150 in a one-to-one manner.

The elastic member 180 may be interposed between the bottom surface 135 of the cover through-hole 133 and the head portion 151 of the fastening bolt 150. The elastic member 180 may be inserted into the groove 134.

The elastic member 180 may be formed of, for example, a rubber material. The elastic member 180 may be provided with a hollow 182 through which the intermediate portion 157 of the fastening bolt 150 passes but the head portion 151 does not pass. The elastic member 180 may have a annular shape.

As shown in FIG. 5, when the elastic member 180 is pressed forward by the head portion 151 while inserted into the groove 134, the elastic member 180 is elastically deformed and the elastic member 180 elastically presses the fastening bolt 150 in a direction opposite to a direction in which the fastening bolt 150 presses the cover 130. In this case, an outer surface of the elastic member 180 may be elastically pressed against the inner surface 136 defining the groove 134.

Accordingly, the cover 130 in contact with the rear surface 105 of the protective panel 101 does not push the protective panel 101 forward with an excessive force. In addition, the protective panel 101 attached to the display module 110 via the double-sided adhesive tape 118 is not separated from the display module 110. Therefore, durability and quality of the display apparatus 100 are improved.

The display apparatus 100 may further include a washer 170. The washer 170 has a hollow 171 through which the body portion 154 of the fastening bolt 150 passes. The washer 170 may be interposed between the rear surface 128 of the frame 120 and the intermediate portion 157 of the fastening bolt 150. The washer 170 may be formed of a metal material such as, for example, stainless steel. The fastening bolt 150 may be fixed due to the washer 170 so that the fastening bolt 150 does not easily loosen from the nut 160.

According to embodiments of the present invention, an elastic member can elastically press a fastening bolt in a direction opposite to a direction in which the fastening bolt presses a cover. Accordingly, the cover in contact with a rear surface of a protective panel does not push the protective panel forward with an excessive force, and the protective panel attached to the display module via the double-sided adhesive tape is not separated from the display module. Therefore, durability and quality of a display apparatus can be improved.

Although the present invention has been disclosed in the form of embodiments and variations thereon, it will be understood that numerous additional modifications and variations could be made thereto without departing from the scope of the invention.

For the sake of clarity, it is to be understood that the use of "a" or "an" throughout this application does not exclude a plurality, and "comprising" does not exclude other steps or elements. The mention of a "unit" or a "module" does not preclude the use of more than one unit or module.

What is claimed is:

1. A display apparatus comprising:
a display module including a display panel;
a protective panel attached to a front surface of the display module via a double-sided adhesive tape;
a frame supporting the display module;
a cover covering a rear surface of the frame and in contact with the protective panel;
a fastening bolt configured to press the cover toward the frame so that the cover is fixed to the frame; and
an elastic member configured to elastically press the fastening bolt in a direction opposite to a direction wherein the fastening bolt presses the cover.

2. The display apparatus according to claim 1, wherein the fastening bolt includes:
a body portion configured to pass through the frame and provided with a male screw pattern on an outer surface thereof;
a head portion having a diameter that is greater than a diameter of the body portion; and
an intermediate portion located between the body portion and the head portion and having a diameter that is greater than the diameter of the body portion and is smaller than the diameter of the head portion.

3. The display apparatus according to claim 2, wherein the cover includes:
a panel overlapping the frame in a front-rear direction of the display apparatus; and
a cover through-hole provided with a groove concavely formed in a rear surface of the panel and an intermediate portion through-hole formed to pass through a bottom surface of the groove and having an inner diameter that is greater than the diameter of the intermediate portion and is smaller than the diameter of the head portion.

4. The display apparatus according to claim 3, wherein the elastic member is interposed between the bottom surface and the head portion and inserted into the groove.

5. The display apparatus according to claim 4, wherein the elastic member is formed of a rubber material and provided with a hollow through which the intermediate portion passes, and the head portion does not pass.

6. The display apparatus according to claim 3, wherein the cover further includes a protective panel contact portion in contact with an outer periphery of a rear surface of the protective panel.

7. The display apparatus according to claim 2, further comprising a nut that includes a female screw pattern engaged with the male screw pattern of the body portion and is in contact with a front surface of the frame.

8. The display apparatus according to claim 7, wherein:
the frame is provided with a body portion through-hole having an inner diameter that is greater than the diameter of the body portion so that the body portion passes through the body portion through-hole;
the nut is provided with a nut body having a hollow wherein the female screw pattern is formed on an inner surface of the nut body; and
the display apparatus further includes a ring-shaped guide protruding rearward from a rear surface of the nut body to surround the body portion and to be inserted into the body portion through-hole.

9. The display apparatus according to claim 8, wherein the nut further includes a friction protrusion that protrudes rearward from the rear surface of the nut body and prevents the nut from rotating relative to the frame while in close contact with the front surface of the frame.

10. The display apparatus according to claim 2, further comprising a washer provided with a washer hollow through which the body portion passes, and which is interposed between a rear surface of the frame and the intermediate portion.
